(19) United States
(12) Patent Application Publication
(10) Pub. No.: US 2018/0196353 A1
(43) Pub. Date: Jul. 12, 2018

(54) MULTIPHOTON ABSORPTION LITHOGRAPHY PROCESSING SYSTEM

(71) Applicant: National Tsing Hua University, Hsinchu City (TW)

(72) Inventors: Chien-Chung Fu, Hsinchu City (TW); Che-Wei Yeh, Changhua County (TW)

(73) Assignee: National Tsing Hua University, Hsinchu City (TW)

(21) Appl. No.: 15/498,361

(22) Filed: Apr. 26, 2017

(30) Foreign Application Priority Data
Jan. 10, 2017 (TW) 106100703

(51) Int. Cl. G03F 7/20; G02B 27/12; G02B 21/26; G02B 21/00; G02B 3/00

(52) U.S. Cl. CPC G03F 7/70191; G02B 27/123; G02B 21/26; G03F 7/70025; G02B 3/0043; G02B 3/0056; G02B 21/0016

(57) ABSTRACT

A multiphoton absorption lithography processing system configured to process a to-be-processed object is provided. The multiphoton absorption lithography processing system includes a femtosecond laser source, a spatial light modulator, a lens array, and a stage. The femtosecond laser source is configured to emit a femtosecond laser beam. The spatial light modulator is configured to modulate the femtosecond laser beam into a modulated beam. The lens array is disposed on a path of the modulated beam and configured to divide the modulated beam into a plurality of sub-beams and make the sub-beams be focused on a plurality of position points at the to-be-processed object, so as to form multiphoton absorption reaction at the position points. The stage is configured to carry the to-be-processed object. The stage and the lens array are adapted to move with respect to each other in three dimensions.

### CROSS-REFERENCE TO RELATED APPLICATION

This application claims the priority benefit of Taiwan application serial no. 106100703, filed on Jan. 10, 2017. The entirety of the above-mentioned patent application is hereby incorporated by reference herein and made a part of this specification.

### BACKGROUND OF THE INVENTION

### 1. Field of the Invention

The invention generally relates to a lithography processing system, in particular, to a multiphoton absorption lithography processing system.

### 2. Description of Related Art

With regard to the two-photon polymerization lithography technology among multiphoton polymerization lithography technologies, a basic concept thereof is integrating two-photon absorption and photopolymerization. The two-photon absorption involves selecting a light of a wavelength that is two times a light sensitive wavelength band of a light sensitive material (for example, a photoresist) to irradiate the light sensitive material; that is, energy of a single photon is only a half of an energy difference between an excited state and a ground state. At this time, photon energy is insufficient to perform a reaction on the photoresist. However, when light with extremely high intensity is irradiated onto the photoresist, a ground state electron of the photoresist has a chance to absorb energy of two photons within an extremely short time (for example, less than 0.1 femtoseconds) and also jumps from a ground state to an excited state of a high energy level. This phenomenon can be regarded as that there is a virtual state at a position of a middle energy level between the state and the excited state, and the electron is subject to two-stage-type excitation from the ground state to the virtual state and further to the excited state, and subsequently, initiates a photopolymerization reaction. The multiphoton absorption means performing irradiation with light of N times the light sensitive wavelength of the photosensitive material, where N is an integer and is greater than or equal to 2.

The two-photon polymerization lithography technology involves exposing photosensitive resin (for example, the photoresist) with focused laser, a nonlinear two-photon polymerization phenomenon is initiated by high energy of a focal spot, as compared with conventional exposure of making the photoresist on all the optical path react, the two-photon polymerization lithography technology only generates a polymerization reaction at the focal spot, a real three-dimensional structure can be processed and completed by using the focal spot in cooperation with a proper laser scanning path.

The two-photon polymerization lithography involves performing processing by using a small focal spot in cooperation with a movement path, and if an overall size of the structure is larger, more processing time needs to be consumed. Generally, because of the limitation of time, sizes of structural elements all fall within a range from several microns to hundreds of microns. Comparison with a processing time for manufacturing a micro-needle array of a large area is used as an example. A micro-needle of a single structure (a diameter of a bottom circle thereof is 60 microns, and the height thereof is 200 microns) has high precision and a long manufacturing time. A single needle needs about 47 minutes, and if a 20×20 array structure is manufactured, 13 days are needed. Therefore, a long manufacturing time is the greatest disadvantage of this processing platform.

### SUMMARY OF THE INVENTION

The invention provides a multiphoton absorption lithography processing system, which can effectively shorten a processing time and meanwhile, maintain processing with high precision.

An embodiment of the invention propose a multiphoton absorption lithography processing system, configured to process a to-be-processed object. The multiphoton absorption lithography processing system includes a femtosecond laser source, a spatial light modulator, a lens array, and a stage. The femtosecond laser source is configured to emit a femtosecond laser beam, and the spatial light modulator is disposed on a path of the femtosecond laser beam and configured to modulate the femtosecond laser beam to a modulated beam. The lens array is disposed on a path of the modulated beam and configured to divide the modulated beam into a plurality of sub-beams and respectively focus the sub-beams on a plurality of position points of the to-be-processed object, so as to generate a multiphoton absorption reaction on the position points. The stage is configured to carry the to-be-processed object. The stage and the lens array are adapted to move with respect to each other in three dimensions to move the position points, on which the sub-beams are focused, with respect to the to-be-processed object in three dimensions in the to-be-processed object, so as to three-dimensionally process the to-be-processed object.

In the multiphoton absorption lithography processing system of the embodiments of the invention, a lens array is used to divide a modulated beam into a plurality of sub-beams, and the sub-beams are respectively focused onto a plurality of position points of a to-be-processed object, so as to generate a multiphoton absorption reaction on the position points. In this way, a speed of lithography processing can be effectively redoubled, a processing time can also be effectively shortened, and meanwhile, processing with high precision can be maintained.

In order to make the foregoing features and advantages of the invention comprehensible, embodiments accompanied with accompanying drawings are described in detail below.

### BRIEF DESCRIPTION OF THE DRAWINGS

FIG. 1 is a schematic diagram of an optical path of a multiphoton absorption lithography processing system according to an embodiment of the invention;

FIG. 2A is a front view of a spatial light modulator in FIG. 1;

FIG. 2B is a partial sectional view of the spatial light modulator in FIG. 2A;

FIG. 3 is a front view of a lens array in FIG. 1;

FIG. 4 is a front view of another variation of the lens array in FIG. 1;

FIG. 5 shows a schematic diagram of an object processed by using the multiphoton absorption lithography processing system in FIG. 1; and

FIG. 6 shows a schematic diagram of another object processed by using the multiphoton absorption lithography processing system n FIG. 1.

### DESCRIPTION OF THE EMBODIMENTS

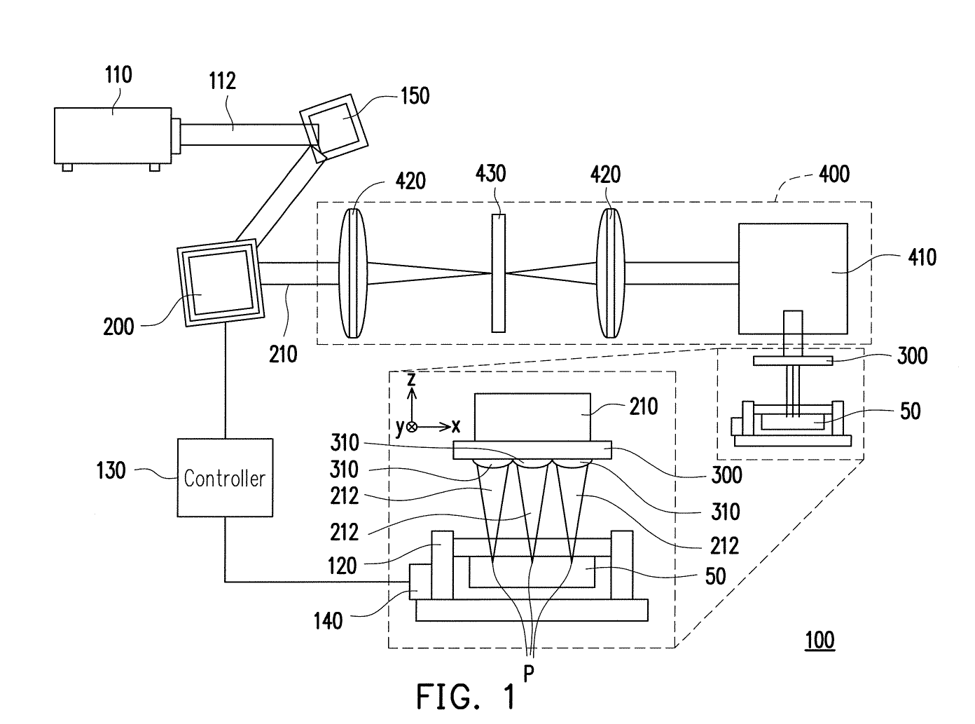

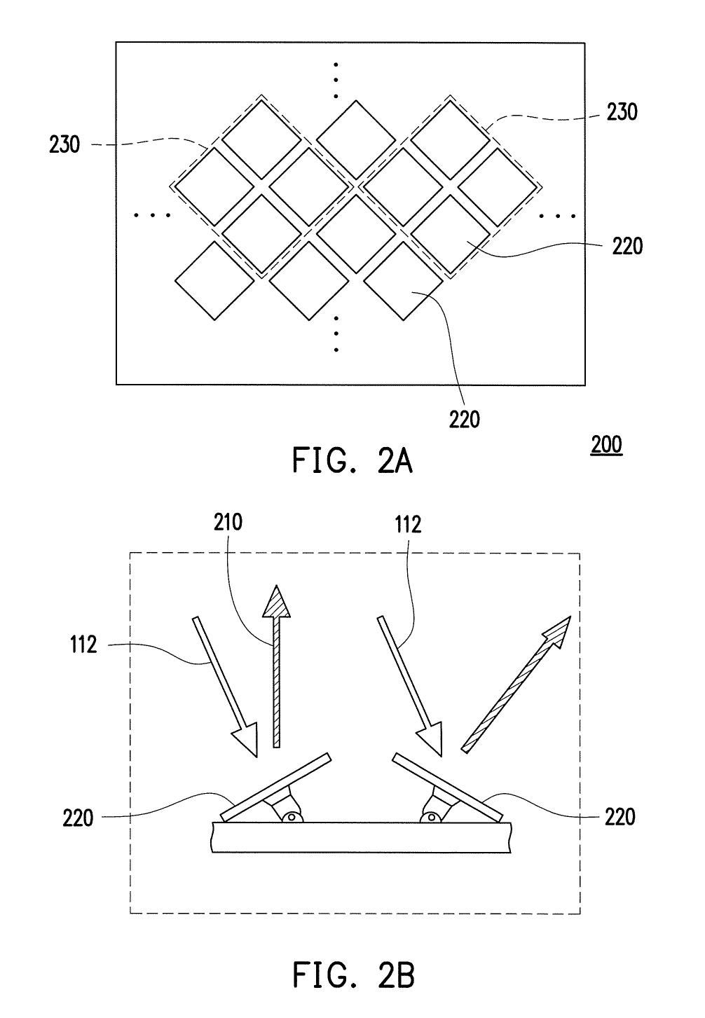

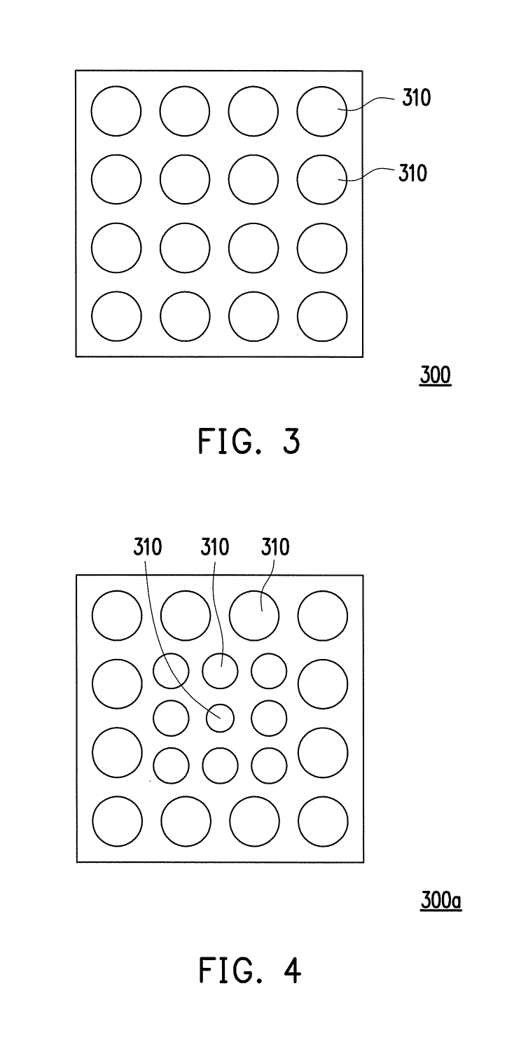

FIG. 1 is a schematic diagram of an optical path of a multiphoton absorption lithography processing system according to an embodiment of the invention, FIG. 2A is a front view of a spatial light modulator in FIG. 1, FIG. 2B is a partial sectional view of the spatial light modulator in FIG. 2A, and FIG. 3 is a front view of a lens array in FIG. 1. Referring to FIG. 1, FIG. 2A, FIG. 2B, and FIG. 3, a multiphoton absorption lithography processing system 100 of this embodiment is configured to process a to-be-processed object 50. In this embodiment, a material of the to-be-processed object 50 is a light sensitive material, for example, a photoresist. The multiphoton absorption lithography processing system 100 includes a femtosecond laser source 110, a spatial light modulator 200, a lens array 300, and a stage 120. The spatial light modulator 110 is configured to emit a femtosecond laser beam 112, where the femtosecond laser means a laser with a time-domain pulse width on the order of femtoseconds.

The spatial light modulator 200 is disposed on a path of the femtosecond laser beam 112 and configured to modulate the femtosecond laser beam 112 to a modulated beam 210. In this embodiment, the spatial light modulator 200, for example, is a digital micro-mirror device (DMD). However, in other embodiments, the spatial light modulator 200 may also be a liquid crystal spatial light modulator (LC-SLM), a liquid-crystal-on-silicon panel (LCOS), a micro-electromechanical-system lens array, or another suitable spatial light modulator.

The lens array 300 is disposed on a path of the modulated beam 210 and configured to divide the modulated beam 210 into a plurality of sub-beams 212 and respectively focus the sub-beams 212 on a plurality of position points P of the to-be-processed object 50, so as to generate a multiphoton absorption reaction on the position points P. The “multiphoton absorption reaction” in the invention includes: a two-photon absorption reaction, a three-photon absorption reaction, a four-photon absorption reaction, or the like, that is, the “multiphoton absorption reaction” means an N-photon absorption reaction, where N is an integer greater than or equal to 2. In this embodiment, the sub-beams 212 generate a two-photon absorption reaction on the position points P, that is, one half of the wavelength of the femtosecond laser beam 112 falls within a light sensitive wavelength band of the light sensitive material of the to-be-processed object 50. If a three-photon absorption reaction is generated on the position points P, one third of the wavelength of the femtosecond laser beam 112 falls within the light sensitive wavelength band of the light sensitive material. Similarly, if an N-photon absorption reaction is generated on the position points P, one Nth of the wavelength of the femtosecond laser beam 112 falls within the light sensitive wavelength band of the light sensitive material.

The stage 120 is configured to carry the to-be-processed object 50. The stage 120 and the lens array 300 are adapted to move with respect to each other in three dimensions to move the position points P, on which the sub-beams 212 are focused, with respect to the to-be-processed object 50 in three dimensions in the to-be-processed object 50, so as to three-dimensionally process the to-be-processed object 50.

In the multiphoton absorption lithography processing system 100 of this embodiment, a lens array 300 is used to divide a modulated beam 210 into a plurality of sub-beams 212, and the sub-beams 212 are respectively focused onto a plurality of position points P of a to-be-processed object 50, so as to generate a multiphoton absorption reaction on the position points P. In this way, a speed of lithography processing can be effectively redoubled, a processing time can also be effectively shortened, and meanwhile, processing with high precision can be maintained. After the to-be-processed object 50 generates a multiphoton absorption reaction on the position points P, a multiphoton polymerization reaction is generated, and further, after the position points P move, with respect to the to-be-processed object 50, in the three dimensions in the to-be-processed object 50, the to-be-processed object 50 is thus three-dimensionally processed. The part, which does not generate a multiphoton polymerization reaction, in the to-be-processed object 50 may be removed by using a developer, so as to further enable the to-be-processed object 50 to be processed into an object with a three-dimensional structure.

In this embodiment, distances from the lens array 300 to the position points P may be far-field optics distances instead of near-field optics distances. For example, the lens array 300 includes a plurality of lenses 310 arranged in an array, and focal lengths of the lenses 310 are greater than a wavelength of the femtosecond laser beam 112 and are less than or equal to 20 millimeter (mm). A lower limit of the focal lengths of the lenses 310 has different values according to the system. For example, when the light sensitive wavelength band of the photoresist of the to-be-processed object 50 is about 400 nanometer (nm), a femtosecond laser beam 112 with a wavelength of 800 nm may be used to perform exposure. Moreover, the definition of the near-field optics is that the focal lengths of the lenses 310 are less than a use wavelength (that is, the indicated 800 nm in this embodiment). However, the focal lengths of the lenses 310 in this embodiment are greater than the use wavelength. Therefore, the optical system performs processing under the far-field optics. In this way, the position points P may move drastically, with respect to the to-be-processed object 50, in a depth direction (that is, being parallel to a direction of an optical axis of the lens 310, i.e. the z-direction in FIG. 1), so as to achieve a preferable three-dimensional processing effect. In an embodiment, during exposure, light power on each position point P may be greater than or equal to 1 milliwatt (mW), so that it is sufficient to generate a multiphoton absorption reaction on the position point P. In addition, the number of lenses 310 in the lens array 300 may decide the number of position points P, and the number of lenses 310 may be designed according to the power of the femtosecond laser source 110, so as to make light power on each position point P greater than or equal to 1 mW. However, the power of each position point P may have different values according to different systems, and may not necessarily be 1 mW, so as to cooperate with different photoresists or different laser specifications, and is also related to a stage movement speed. Generally, if the peak power of the femtosecond laser beam 112 has higher energy, and a processing speed is lower, the needed minimum power of each position point P is lower.

In this embodiment, the multiphoton absorption lithography processing system 100 further includes an imaging device 400, disposed on a path of the modulated beam 210 and located between the spatial light modulator 200 and the lens array 300, so as to form an image of the spatial light modulator 200 on the lens array 300. The imaging device 400 may include a microscope 410 and at least one lens 420 (in FIG. 1, the imaging device 400 including two lenses 420 is used as an example). The microscope 410 is disposed on the path of the modulated beam 210 and located between the spatial light modulator 200 and the lens array 300. The microscope 420 is disposed on the path of the modulated beam 210 and located between the spatial light modulator 200 and the microscope 410. In this embodiment, the imaging device 400 further includes an aperture stop 430, disposed between the two lenses 420, so as to form a 4F optical system in the Fourier optics by the spatial light modulator 200, the two lenses 420, the aperture stop 430, and the microscope 410. An aperture of the aperture stop 430 may be adjustable, so as to help filtering, thereby effectively reducing noise in the modulated beam 210.

In addition, in this embodiment, the multiphoton absorption lithography processing system 100 further includes a reflecting mirror 150, disposed on a path of the femtosecond laser beam 112 and located between the femtosecond laser source 110 and the spatial light modulator 200, so as to reflect the femtosecond laser beam 112 from the femtosecond laser source 110 to the spatial light modulator 200. The reflecting mirror 150 may be configured to reduce the volume of the multiphoton absorption lithography processing system 100. However, in other embodiments, the multiphoton absorption lithography processing system 100 may not include a reflecting mirror 150, and the femtosecond laser source 110 emits a femtosecond laser beam 112 toward the spatial light modulator 200 and transmits the femtosecond laser beam 112 to the spatial light modulator 200.

In this embodiment, the multiphoton absorption lithography processing system 100 further includes a controller 130 and an actuator 140. The controller 130 is electrically connected to the spatial light modulator 200, and the actuator 140 is configured to enable the stage 120 and the lens array 300 to move, with respect to each other, in the three dimensions. In this embodiment, the actuator 140, for example, is a motor, which is connected to the stage 120, so as to enable the stage 120 to move in the three dimensions, and in this embodiment, the stage 120 is only connected to the to-be-processed object 50 and does not move the lens array 300, and the lens array 300 is fixed onto a platform of the microscope 410. However, in other embodiments, the actuator 140 may be connected to a whole optical system before the lens array 300 (for example, a whole optical system including the lens array 300, the imaging device 400, the spatial light modulator 200, the reflecting mirror 150, the femtosecond laser source 110), so as to enable the whole optical system before the lens array 300 to move in the three dimensions and the stage 120 to keep still. The foregoing three dimensions, for example, are three dimensions including an x-direction, a y-direction, a z-direction in FIG. 1, where the z-diction, for example, is a direction parallel to an optical axis of the lens 310, both the x-direction and y-direction are perpendicular to the z-direction, and the x-direction is perpendicular to the y-direction.

The controller 130 is also electrically connected to the actuator 140 and enables an action of the spatial light modulator 20 to cooperate with an action of the actuator 140. Specifically, in this embodiment, a digital micro-mirror device (DMD) is used as an example of the spatial light modulator 200 and includes a plurality of micro-mirrors 220, the micro-mirror 220 may be turned over to an angle as an on-state of the micro-mirror 220 on the left of FIG. 2B or be turned over to an angle as an off-state of the micro-mirror 220 on the right of FIG. 2B. When the micro-mirror 220 is in the on-state, the micro-mirror 220 may reflect a part of the femtosecond laser beam 112 irradiated thereon to the imaging device 400 and further, to the lens array 300, and an image of a bright spot is formed at a corresponding position of the lens array 300. When the micro-mirror 220 is in the off-state, the micro-mirror 220 may reflect a part of the femtosecond laser beam 112 irradiated thereon to a direction that deviates from the imaging device 400 and does not reach the lens array 300, and in this way, an image of a dark spot is formed at a corresponding position of the lens array 300. In a frame time on a microscopic time axis, the spatial light modulator 200 may control, according to a signal from the controller 130, a ratio of time duration of a micro-mirror 220 in the on-state to time duration of the micro-mirror 220 in the off-state, so as to control brightness of a bright spot at a position corresponding to the lens array 300 on a macroscopic time axis, for example, average brightness of the bright spot in one frame time or several frame times. In this way, when the controller 130 controls the actuator 140 to enable the stage 120 to move along a path, the controller 130 may control that the micro-mirror 220 is in the on-state or off-state, so as to determine whether the position point P is exposed or not exposed when the position point P moves to this position, thereby further processing the to-be-processed object 50 in the three dimensions.

In an embodiment, the controller 130 is, for example, a central processing unit (CPU), a microprocessor, a digital signal processor (DSP), a programmable controller, a programmable logic device (PLD), or other similar devices, or a combination of the said devices, which are not particularly limited by the invention. Further, in an embodiment, each of the functions of the controller 130 may be implemented as a plurality of program codes. These program codes will be stored in a memory, so that these program codes may be executed by the controller 130. Alternatively, in an embodiment, each of the functions of the controller 130 may be implemented as one or more circuits. The invention is not intended to limit whether each of the functions of the controller 130 is implemented by ways of software or hardware.

In this embodiment, as shown in FIG. 3, areas of the lenses of the lens array 300 are substantially the same as each other. The wording “substantially the same” herein means that errors of the areas of the lenses 310 are less than 10% of the minimum area of the lens 310. However, because light intensity of the femtosecond laser beam 112 generally presents Gaussian distribution, the light intensity of the femtosecond laser beam 112 irradiated on an edge of the spatial light modulator 200 is weaker than the light intensity of the femtosecond laser beam 112 irradiated on a center of the spatial light modulator 200. In order to overcome this problem, the controller 130 may be used to control the spatial light modulator 200 to make an effective light sending ratio (for example, a ratio of time duration of the micro-mirror 220 in the on-state to time duration of the micro-mirror in the off-state in a frame time) provided by a bright pixel of the spatial light modulator 200 present an increasing tendency (for example, progressively increasing) from a center to an edge, so as to equalize light energy on the position points P. In this way, light energy on either a position point P located on an edge or a position points P on a center is more consistent, and therefore, the same exposure time can be used on the position points P.

In another embodiment, as shown in FIG. 4, areas of the lenses 310 of a lens array 300a present an increasing tendency (for example, progressively increasing) from a center of the lens array 300a to an edge of the lens array 300a, so as to equalize light energy on the position points P. At this time, an effective light sending ratio (for example, a ratio of time duration of the micro-mirror 220 in the on-state to time duration of the micro-mirrorin the off-state in a frame time) provided by a bright pixel of the spatial light modulator 200 may be kept consistent from a center of the spatial light modulator 200 to an edge thereof Because areas of the lenses 310 on the edge of the lens array 300a are relatively large, and more light energy can be collected, a situation that light intensity of the femtosecond laser beam 112 on the edge is relatively weak can be compensated for. In this way, light energy on either a position point P located on an edge or a position points P on a center is consistent, and therefore, the same exposure time can be used on the position points P. However, in other embodiments, the areas of the lenses 310 of the lens array 300a do not need to present the foregoing increasing tendency, and any design manner that can equalize light energy on the position points P is a manner that can be implemented.

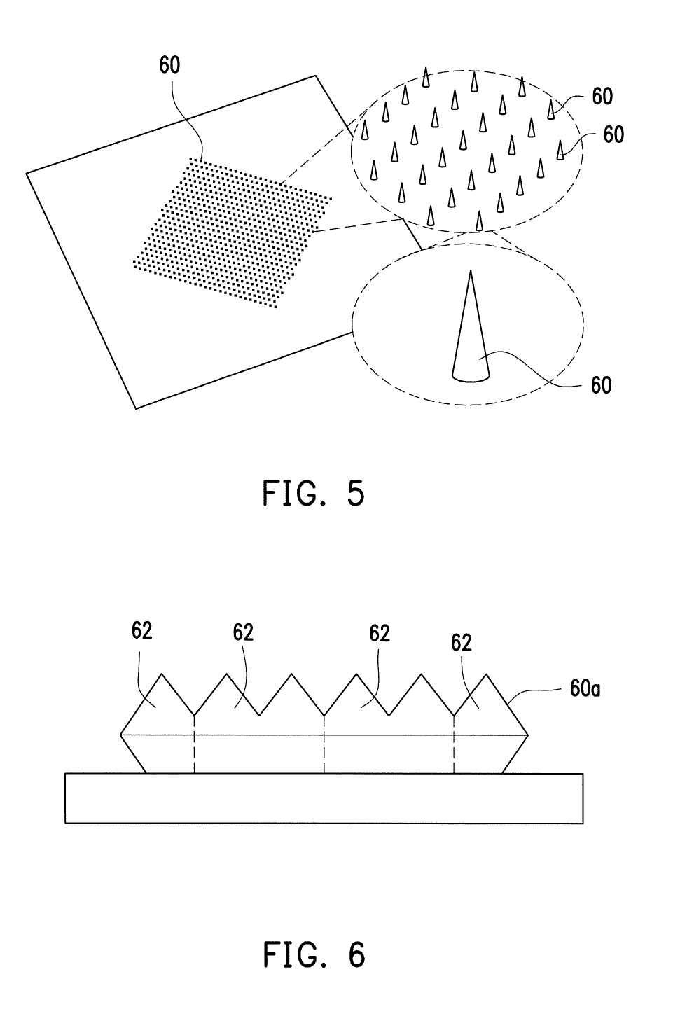

In this embodiment, the spatial light modulator 200 has a plurality of regions 230, and each region 230 may include one or more micro-mirrors 220. Lights from the regions 230 are respectively projected to the lenses 310 of the lens array 300. When the controller 130 controls the actuator 140 to make the stage 120 move along a path (which, for example, is an indirect path to arrive at a plurality of positions in a specific three-dimensional space), the controller 130 enables actions of the regions 230 for presenting a bright state or a dark state to be the same (the bright state may be contributed by the micro-mirror 220 located on the on-state, and the dark state may be formed by the micro-mirror 220 located on the off-state), so as to process the to-be-processed object into a plurality of repeated three-dimensional structures, for example, a plurality of repeated needle-shaped structures 60 in FIG. 5.

However, in another embodiment, as shown in FIG. 6, when the controller 130 controls the actuator 140 to make the stage 120 move along a path, the controller 130 enables actions of the regions 230 for presenting a bright state or a dark state to be not completely the same, so as to splice a plurality of three-dimensional structure 62 respectively processed by the sub-beams 212 into a complete three-dimensional structure 60a, and the three-dimensional structure 62 respectively processed by the sub-beams 212 are not completely the same.

Further referring to FIG. 1, lenses 310 in the lens array 300 of this embodiment, for example, are micro lenses and can be manufactured by means of multiphoton polymerization lithography processing (for example, two-photon polymerization lithography processing), so as to achieve preferable precision.

In conclusion, in the multiphoton absorption lithography processing system of the embodiments of the invention, a lens array is used to divide a modulated beam into a plurality of sub-beams, and the sub-beams are respectively focused onto a plurality of position points of a to-be-processed object, so as to generate a multiphoton absorption reaction on the position points. In this way, a speed of lithography processing can be effectively redoubled, a processing time can also be effectively shortened, and meanwhile, processing with high precision can be maintained.

It will be apparent to those skilled in the art that various modifications and variations can be made to the structure of the invention without departing from the scope or spirit of the invention. In view of the foregoing, it is intended that the invention covers modifications and variations of this invention provided they fall within the scope of the following claims and their equivalents.

What is claimed is:

1. A multiphoton absorption lithography processing system, configured to process a to-be-processed object, comprising:
a femtosecond laser source, configured to emit a femtosecond laser beam;
a spatial light modulator, disposed on a path of the femtosecond laser beam and configured to modulate the femtosecond laser beam to a modulated beam;
a lens array, disposed on a path of the modulated beam and configured to divide the modulated beam into a plurality of sub-beams and respectively focus the sub-beams on a plurality of position points of the to-be-processed object, so as to generate a multiphoton absorption reaction on the position points; and
a stage, configured to carry the to-be-processed object, wherein the stage and the lens array are adapted to move with respect to each other in three dimensions to move the position points, on which the sub-beams are focused, with respect to the to-be-processed object in three dimensions in the to-be-processed object, so as to three-dimensionally process the to-be-processed object.

2. The multiphoton absorption lithography processing system according to claim 1, wherein the lens array comprises a plurality of lenses arranged in an array, and focal lengths of the lenses are greater than a wavelength of the femtosecond laser beam and are less than or equal to 20 mm.

3. The multiphoton absorption lithography processing system according to claim 1, further comprising an imaging device, disposed on the path of the modulated beam, located between the spatial light modulator and the lens array, and configured to form an image of the spatial light modulator on the lens array.

4. The multiphoton absorption lithography processing system according to claim 3, wherein the imaging device comprises:
a microscope, disposed on the path of the modulated beam and located between the spatial light modulator and the lens array; and
at least one lens, disposed on the path of the modulated beam and located between the spatial light modulator and the microscope.

5. The multiphoton absorption lithography processing system according to claim 4, wherein the at least one lens comprises two lenses, and the imaging device further comprises an aperture stop, disposed between the two lenses.

6. The multiphoton absorption lithography processing system according to claim 1, wherein the lens array comprises a plurality of lenses arranged in an array, and areas of the lenses present an increasing tendency from a center of the lens array to an edge of the lens array, so as to equalize light energy on the position points.

7. The multiphoton absorption lithography processing system according to claim 1, further comprising a controller, electrically connected to the spatial light modulator, wherein the lens array comprises a plurality of lenses arranged in an array, areas of the lens are substantially the same as each other, the controller controls the spatial light modulator to make an effective light sending ratio provided by a bright pixel of the spatial light modulator present an increasing tendency from a center of the spatial light modulator to an edge thereof, so as to equalize light energy on the position points.

8. The multiphoton absorption lithography processing system according to claim 1, further comprising:
a controller, electrically connected to the spatial light modulator; and
an actuator, configured to enable the stage and the lens array to move with respect to each other in the three dimensions, wherein the controller is also electrically connected to the actuator and enables an action of the spatial light modulator to cooperate with an action of the actuator.

9. The multiphoton absorption lithography processing system according to claim 8, wherein the spatial light modulator comprises a plurality of regions, the lens array comprises a plurality of lenses arranged in an array, lights from the regions are projected to the lenses respectively, and when the controller controls the actuator to enable the stage to move along a path, the controller enables actions of the regions for presenting a bright state or a dark state to be the same, so as to process the to-be-processed object into a plurality of repeated three-dimensional structures.

10. The multiphoton absorption lithography processing system according to claim 8, wherein the spatial light modulator comprises a plurality of regions, the lens array comprises a plurality of lenses arranged in an array, lights from the regions are projected to the lenses respectively, and when the controller controls the actuator to enable the stage to move along a path, the controller enables actions of the regions for presenting a bright state or a dark state to be not completely the same, so as to enable a plurality of three-dimensional structures respectively processed by the sub-beams are spliced into a complete three-dimensional structure, and the three-dimensional structures respectively processed by the sub-beams are not completely the same.

11. The multiphoton absorption lithography processing system according to claim 1, wherein a material of the to-be-processed object is a light sensitive material, the multiphoton absorption reaction is a two-photon absorption reaction, and one half of the wavelength of the femtosecond laser beam falls within a light sensitive wavelength band of the light sensitive material.
